(19) United States
(12) Patent Application Publication
(10) Pub. No.: US 2009/0219088 A1
(43) Pub. Date: Sep. 3, 2009

(54) APPARATUS AND METHOD FOR CORRECTING NON-LINEAR DISTORTION BASED ON CHARACTERISTIC MODELING OF HIGH POWER AMPLIFIER

(75) Inventors: Jae-Hyun Seo, Daejon (KR); Heung-Mook Kim, Daejon (KR); Yong-Tae Lee, Daejon (KR); Ho-Min Eum, Daejon (KR); Sung-Ik Park, Daejon (KR); Seung-Won Kim, Daejon (KR); Soo-In Lee, Daejon (KR)

Correspondence Address: CANTOR COLBURN, LLP, 20 Church Street, 22nd Floor, Hartford, CT, 06103, US

(73) Assignee: Electronics and Telecommunications Research, Daejon (KR)

(21) Appl. No.: 12/089,475

(22) PCT Filed: Sep. 28, 2006
(86) PCT No.: PCT/KR2006/003885

§ 371 Date: Jan. 19, 2009

(30) Foreign Application Priority Data
Oct. 7, 2005 (KR) 10-2005-0094438

(51) Int. Cl. H03F 1/26

(52) U.S. Cl. 330/149

(57) ABSTRACT

An apparatus for correcting a non-linear distortion includes a pre-distorter for pre-distorting a transmit signal inputted from an external apparatus based on pre-distortion characteristics outputted from a pre-distortion characteristic predictor; a modulator for modulating the pre-distorted signal to thereby generate a modulated signal; a frequency up-converter for up-converting a frequency of the modulated signal to thereby generate an up-converted signal; a high power amplifier for amplifying the up-converted signal to a high power amplified signal; a frequency down-converter for down-converting a frequency of the high power amplified signal, thereby generate a down-converted signal; a demodulator for demodulating the down-converted signal, to thereby generate a demodulated signal; a high power amplifying characteristic predictor for predicting characteristics of the high power amplifier based on the pre-distorted signal and the demodulated signal; and a pre-distortion characteristic predictor for predicting the pre-distortion characteristics based on the pre-distorted signal and the predicted high power amplifying characteristics.

### TECHNICAL FIELD

The present invention relates to an apparatus and a method for correcting a non-linear distortion based on characteristic model of a high power amplifier; and, more particularly, to an apparatus and a method for correcting a non-linear distortion of a high power amplifier by adapting an output signal of a high power amplifying characteristic predictor to a pre-distortion characteristic predictor, and adapting an output signal of the pre-distortion characteristic predictor to the pre-distorter.

### BACKGROUND ART

In a general communication and broadcasting system, a high power amplifier is necessary for transmitting a transmit signal in a wide area. A general high power amplifier has characteristics that a phase and an amplitude of an output signal are non-linear to an amplitude of an input signal.

In general, when a communication signal of a communication apparatus including a satellite, a mobile communication, a radio relay link and a radar is transmitted, a high power amplifier amplifies the communication signal.

As above mentioned, a high power amplifier is used for amplifying an output signal before transmitting the communication signal. However, the high power amplifier distorts a transmit signal non-linearly because the high power amplifier has an amplitude modulation/amplitude modulation (AM/AM) or amplitude modulation/phase modulation (AM/PM) characteristics.

A transmit signal is distorted by a non-linear effect generated from the high power amplifier distort, and an interference between neighboring channels may be generated by enlarging a bandwidth of the communication signal. A pre-distortion technique for linearizing characteristics of the high power amplifier is one of methods to solve the above problem.

A conventional method for correcting non-linear characteristics of the high power amplifier is classified into two kinds of schemes. First scheme is an input signal back-off which uses a linear region of the high power amplifier. Secondary scheme is a pre-distortion scheme which pre-distorts an input signal of the high power amplifier.

That is, since the high power amplifier has largest non-linear distortion characteristics in a high input signal, a general scheme for decreasing non-linear distortion characteristics is to use not a power of all input signal of the high power amplifier but a power of a linear characteristic region by decreasing the amplitude of the input signal. However, the above scheme is not based on an AM/PM modulation effect or high power amplifier characteristics which are variable according to a time.

A pre-distortion which linearizes an input signal of a high power having non-linear amplifying characteristics of a high power amplifier corrects demerit of the first scheme. That is, the pre-distorter performs an inverse distortion for correcting the distortion of the high power amplifier.

FIG. 1 is a block diagram showing an apparatus for correcting a pre-distortion using a conventional high power amplifying characteristic predictor.

First, a transmit signal is inputted to a pre-distorter 101. The pre-distorted signal from the pre-distorter 101 is modulated by a modulator 102. The modulated signal is converted into a radio frequency signal by a frequency up converter 103. The up-converted radio frequency signal is amplified by a high power amplifier 104, and the amplified radio frequency signal is transmitted through an antenna.

A part of the output signal of the high power amplifier 104 is divided and down-converted by a frequency down converter 105. The down-converted signal is demodulated by a demodulator 106.

Subsequently, if the pre-distorted signal from the pre-distorter 101 and the demodulated signal from the demodulator 106 are inputted to a high power amplifying characteristic predictor 107 respectively, the high power amplifying characteristic predictor 107 predicts characteristics of the high power amplifier based on the pre-distorted signal and the demodulated signal.

An inverse function converter 108 obtains an inverse characteristic function by using the predicted characteristics of the high power amplifier. The inverse characteristic function obtained by the inverse function converter 108 is used as a pre-distorter.

Similar schemes to the above scheme described with reference to FIG. 1 are disclosed in the U.S. Pat. No. 5,049,832 (Amplifier Linearization by adaptive pre-distortion), U.S. Pat. No. 6,072,364 (Adaptive digital pre-distortion for power amplifiers with real time modeling of memoryless complex gains), U.S. Pat. No. 5,929,703 (Method and device for modeling AM-AM and AM-FM characteristics of an amplifier, and corresponding pre-distortion), and Korean patent No. 10-0315425 (Apparatus and method for high speed adaptive pre-distortion using lookup table).

However, since theses schemes obtain directly an inverse function after obtaining a forward characteristic function of a high power amplifier, these schemes have problems such that the complexity of a calculation is increased, and are sensitive to a measuring error or a system error.

FIG. 2 is a block diagram showing an apparatus for correcting a pre-distortion using another conventional pre-distortion characteristic predictor.

First, a transmit signal is inputted to a pre-distorter 201. The pre-distorted signal from the pre-distorter 201 is modulated by a modulator 202. The modulated signal is converted into a radio frequency signal by a frequency up converter 203. The up-converted radio frequency signal is amplified by a high power amplifier 204, and the amplified radio frequency signal is transmitted through an antenna.

A part of the output signal of the high power amplifier 204 is divided and down-converted by a frequency down converter 205. The down-converted signal is demodulated by a demodulator 206.

Subsequently, if the pre-distorted signal from the pre-distorter 201 and the demodulated signal from the demodulator 206 are inputted to a pre-distortion characteristic predictor 207, the pre-distortion characteristic predictor 207 is operated as a pre-distorter by obtaining an inverse characteristic function of the high power amplifier based on the pre-distorted signal and the demodulated signal.

Similar scheme to the scheme described with reference to FIG. 2 is described by “Hua Qian” and “G. Tong Zhou”, “Orthogonal Polynomials for Power Amplifier Modeling and Pre-distorter Design”, “IEEE Transaction on Vehicular Technology, Vol. 53, No. 5, pp 1468-1479”. The scheme described in FIG. 2 reduces a calculation quantity and uses a less amplitude of input/output signal of the high power amplifier than the scheme described in FIG. 1 by obtaining a characteristic function of a pre-distorter.

However, above-mentioned scheme has performance deterioration by an extraction error when an output signal of the high power amplifier is obtained.

That is, the above-mentioned scheme needs many signal samples for calculating a characteristic modeling of a high power amplifier, and is sensitive to a measuring error. In a case that a model of pre-distorter is obtained directly, a time variable effect and a noise of the high power amplifier are sensitive.

### DISCLOSURE

### Technical Problem

It is, therefore, an object of the present invention to provide an apparatus and a method for correcting a non-linear distortion based on a characteristic model of a high power amplifier, for correcting a non-linear distortion of a high power amplifier by adapting an output signal of a high power amplifying characteristic predictor to a pre-distortion characteristic predictor, and adapting an output signal of the pre-distortion characteristic predictor to the pre-distorter.

That is, an object of the present invention is to provide an apparatus and a method for correcting a non-linear distortion using a characteristic model of a high power amplifier for correcting a non-linear distortion of a high power amplifier by adapting an output signal of a high power amplifying characteristic predictor to a pre-distortion characteristic predictor, and adapting an output signal of the pre-distortion characteristic predictor to the pre-distorter after a high power amplifying characteristic predictor predicts characteristics of the high power amplifier based on the output signals of the pre-distorter and the high power amplifier.

### Technical Solution

In accordance with one aspect of the present invention, there is provided an apparatus for correcting a non-linear distortion, including: An apparatus for correcting a non-linear distortion includes a pre-distorter for pre-distorting a transmit signal inputted from an external apparatus based on pre-distortion characteristics outputted from a pre-distortion characteristic predictor; a modulator for modulating the pre-distorted signal to thereby generate a modulated signal; a frequency up-converter For up-converting a frequency of the modulated signal to thereby generate an up-converted signal; a high power amplifier for amplifying the up-converted signal to a high power amplified signal; a frequency down-converter for down-converting a frequency of the high power amplified signal, thereby generate a down-converted signal; a demodulator for demodulating the down-converted signal, to hereby generate a demodulated signal; a high power amplifying characteristic predictor for predicting characteristics of the high power amplifier based on the pre-distorted signal and the demodulated signal; and a pre-distortion characteristic predictor for predicting the pre-distortion characteristics based on the pre-distorted signal and the predicted high power amplifying characteristics.

In accordance with another aspect of the present invention, there is provided a method for correcting a non-linear distortion, including the steps of: a) at a high power amplifying characteristic predictor, generating a characteristic model of a high power amplifier by predicting characteristics of the high power amplifier based on a pre-distorted signal which is outputted from a pre-distorter and a demodulated signal which is outputted from a demodulator; b) at a pre-distortion characteristic predictor, predicting pre-distortion characteristics based on the pre-distorted signal and the predicted characteristics model of the high power amplifier; and c) adapting the predicted pre-distortion characteristics to the pre-distorter.

### ADVANTAGEOUS EFFECTS

The present invention corrects a non-linear distortion of a high power amplifier by adapting an output signal of a high power amplifying characteristic predictor to a pre-distortion characteristic predictor, and adapting characteristics of a pre-distorter, which is predicted by the pre-distortion characteristic predictor, to the pre-distorter after a high power amplifying characteristic predictor predicts characteristics of the high power amplifier based on the output signals of the pre-distorter and the high power amplifier.

That is, the present invention decreases a measuring error based on an output signal of the pre-distorter and an output signal of characteristic model of the high power amplifier by using the high power amplifying characteristic amplifier. And, the present invention decreases a measuring error and a deterioration of performance by adapting the output signal of the characteristic model of the high power amplifier to the pre-distortion characteristic predictor.

### DESCRIPTION OF DRAWINGS

The above and other objects and features of the present invention will become better understood with regard to the following description of the preferred embodiments given in conjunction with the accompanying drawings, in which:

FIG. 1 is a block diagram showing an apparatus for correcting a pre-distortion using a conventional high power amplifying characteristic predictor;

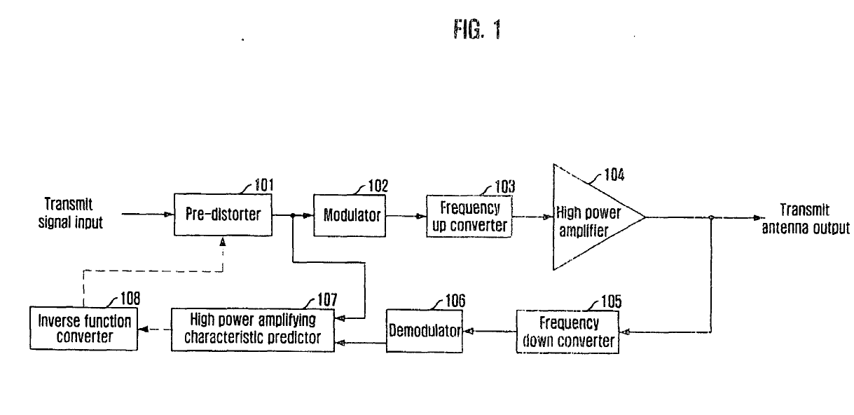

FIG. 2 is a block diagram showing an apparatus for correcting a pre-distortion using a conventional pre-distortion characteristic predictor;

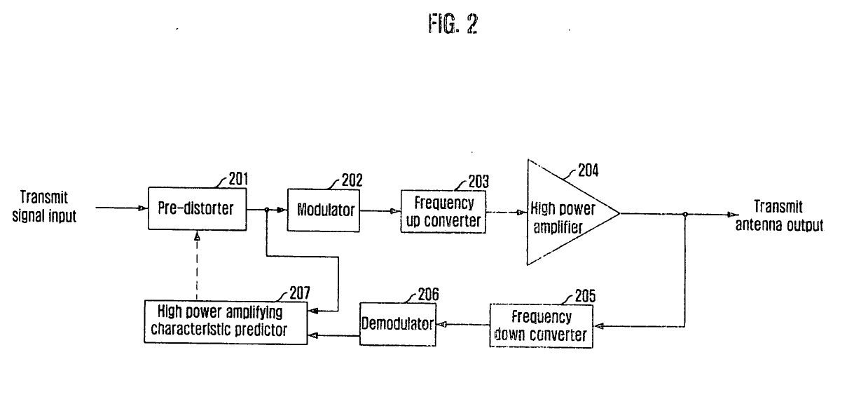

FIG. 3 is a block diagram showing an apparatus for correcting a non-linear distortion using a characteristic modeling or a high power amplifier in accordance with an embodiment of the present invention; and

FIG. 4 is a flow chart showing a method for correcting a non-linear distortion using a characteristic modeling of the high power amplifier in accordance with an embodiment of the present invention.

### BEST MODE OF THE INVENTION

Other objects and aspects of the invention will become apparent from the following description of the embodiments with reference to the accompanying drawings, which is set forth hereinafter.

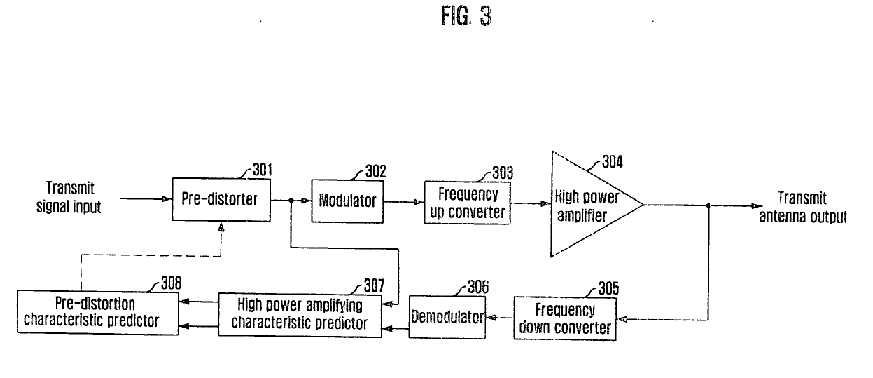

FIG. 3 is a block diagram showing an apparatus for correcting a non-linear distortion using a characteristic modeling of a high power amplifier in accordance with an embodiment of the present invention.

As shown in FIG. 3, an apparatus for correcting a non-linear distortion using a characteristic modeling of a high power amplifier in accordance with an embodiment of the present invention includes a pre-distorter 301 a modulator 302, a frequency up-converter 303, a high power amplifier 304, a frequency down-converter 305, a demodulator 306, a high power amplifying characteristic predictor 307 and a pre-distortion characteristic predictor 308.

The pre-distorter 301 pre-distorts a transmit signal inputted from an external apparatus based on characteristics of the pre-distorter from the pre-distortion characteristic predictor 308, and outputs the pre-distorted transmit signal to the modulator 302.

The modulator 302 modulates the pre-distorted transmit signal. The frequency up-converter 303 up-converts the signal outputted from the modulator 302.

The high power amplifier 304 amplifies the signal outputted from the frequency up-converter 303 to a high power. The frequency down-converter 305 down-converts the signal outputted from the high power amplifier 304.

The demodulator 306 demodulates the signal outputted from the frequency down-converter 305. The high power amplifying characteristic predictor 307 predicts characteristics of the high power amplifier 304 based on the output signal of the pre-distorter 301 and the output signal of the demodulator 306.

The pre-distortion characteristic predictor 308 predicts characteristics of the pre-distorter based on the output signal of the pre-distorter and characteristics of the high power amplifier predicted by the high power amplifying characteristic predictor 307.

A detailed configuration and an operation of each component will be described as below.

First, a transmit signal is inputted to the pre-distorter 301. The pre-distorted signal from the pre-distorter 301 is modulated by the modulator 302. The modulated signal is converted into a radio frequency signal by the frequency up converter 303. The up-converted radio frequency signal is amplified by the high power amplifier 304, and the amplified radio frequency signal is transmitted through an antenna.

A part of the output signal of the high power amplifier 304 is divided. The divided output signal is down-converted by the frequency down converter 305. The down-converted signal is demodulated by the demodulator 306.

Subsequently, if the pre-distorted signal from the pre-distorter 301 and the demodulated signal from the demodulator 306 are inputted to the high power amplifying characteristic predictor 307 respectively, the high power amplifying characteristic predictor 307 predicts the characteristics of the high power amplifier based on the output signal of the pre-distorter and the demodulated signal of the demodulator 306. The high power amplifying characteristic predictor 307 obtains a characteristic model of the high power amplifier 304.

That is, the high power amplifying characteristic predictor 307 receives the pre-distorted signal outputted from the pre-distorter 301, but does not adapt directly the demodulated signal outputted from the demodulator 306.

After the high power amplifying characteristic predictor 307 obtains the characteristic model of the high power amplifier 304 based on the output signal of the pre-distorter and the demodulated signal of the demodulator, the high power amplifying characteristic predictor 307 outputs a characteristic model signal of the high power amplifier 304.

The pre-distortion characteristic predictor 308 predicts the characteristics of the pre-distorter based on the output signal of the pre-distorter and the characteristics of high power amplifier predicted by the high power amplifying characteristic predictor 307, and outputs the predicted characteristics to the pre-distorter 301.

The pre-distorter 301 pre-distorts the transmit signal inputted from an external apparatus based on the characteristics of pre-distorter from the pre-distortion characteristic predictor 308, and outputs the pre-distorted transmit signal to the modulator 302.

As aforementioned, the pre-distortion characteristic predictor 308 accurately obtains an inverse characteristic function of the high power amplifier by using the output signal of the characteristic model of the high power amplifier.

The inverse characteristic function of the high power amplifier is adapted to the pre-distorter 301 which receives the transmit signal from an external apparatus.

That is, the output signal of the high power amplifier 304 is not directly adapted to the pre-distortion characteristic predictor 308.

After the characteristic model of the high power amplifier 304 is obtained through the high power amplifying characteristic predictor 307, a measuring error and a deterioration of performance may be decreased by adapting the output signal of the characteristic model of the high power amplifier 304 to the pre-distortion characteristic predictor 308.

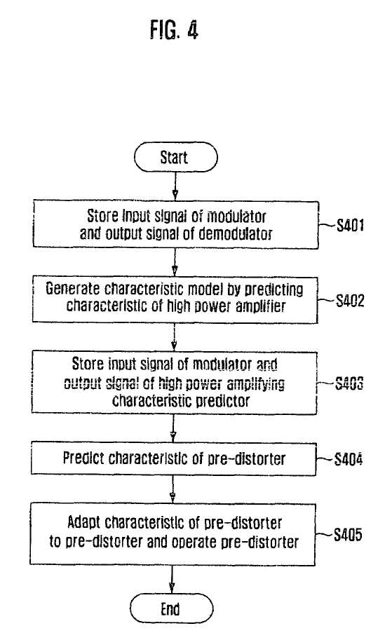

FIG. 4 is a flow chart showing a method for correcting a non-linear distortion using a characteristic modeling of the high power amplifier in accordance with an embodiment of the present invention.

First, the output signals of the pre-distorter 301 and the demodulator 302 are stored at step S401.

A characteristic model of the high power amplifier 304 is generated by predicting characteristics of a high power amplifier 304 based on the output signals of a pre-distorter 301 and the demodulator 302 at step S402.

The output signal of the pre-distorter 301 and the characteristic model of the high power amplifier 304 outputted from the high power amplifying characteristic predictor 307 are re-stored at step S403.

Subsequently, the pre-distortion characteristic predictor 308 predicts characteristics of the pre-distorter 301 based on the output signals of the pre-distorter 301 and the characteristic model of the high power amplifier from the high power amplifying characteristic predictor 307 at step S404.

That is, the pre-distortion characteristic predictor 308 obtains coefficients for the pre-distorter 301.

The output signal of the high power amplifier 304 is linearlized by adapting the characteristics of pre-distorter 301, which is predicted by the pre-distortion characteristic predictor 308, to the pre-distorter 301 and operating the pre-distorter 301 at step S405.

Time-variable characteristics of a system are chased by repeatedly adapting the above steps S401 to S405.

The method of the present invention as mentioned above may be implemented by a software program and stored in a computer-readable storage medium such as CD-ROM, RAM, ROM, floppy disk, hard disk, optical magnetic disk, etc. This process may be readily carried out by those skilled in the art; and therefore, details of thereof are omitted here.

The present application contains subject matter related to Korean patent application No. 2005-0094438, filed in the Korean patent office on Oct. 7, 2005, the entire contents of which being incorporated herein by reference.

While the present invention has been described with respect to certain preferred embodiments, it will be apparent to those skilled in the art that various changes and modifications may be made without departing from the spirits and scope of the invention as defined in the following claims.

What is claimed is:

1. An apparatus for correcting a non-linear distortion, comprising:
a pre-distorting means for pre-distorting a transmit signal inputted from an external apparatus based on pre-distortion characteristics outputted from a pre-distortion characteristic predicting means;
a modulating means for modulating the pre-distorted signal to thereby generate a modulated signal;
a frequency up-converting means for up-converting a frequency of the modulated signal to thereby generate an up-converted signal;
a high power amplifying means for amplifying the up-converted signal to a high power amplified signal;
a frequency down-converting means for down-converting a frequency of the high power amplified signal, thereby generate a down-converted signal;
a demodulating means for demodulating the down-converted signal, to thereby generate a demodulated signal;
a high power amplifying characteristic predicting means for predicting characteristics of the high power amplifying means based on the pre-distorted signal and the demodulated signal; and
a pre-distortion characteristic predicting means for predicting the pre-distortion characteristics based on the pre-distorted signal and the predicted high power amplifying characteristics.

2. The apparatus as recited in claim 1, wherein the high power amplifying characteristic predicting means obtains a characteristic model of the high power amplifying means and outputs the obtained characteristic model to the pre-distortion characteristic predicting means,
wherein the pre-distortion characteristic predicting means obtains an inverse characteristic function of the high power amplifying means based on the pre-distorted signal and the characteristic model of the high power amplifying means which is obtained by the high power amplifying characteristic predicting means.

3. A method for correcting a non-linear distortion, comprising the steps of:
a) at a high power amplifying characteristic predicting means, generating a characteristic model of a high power amplifying means by predicting characteristics of the high power amplifying means based on a pre-distorted signal which is outputted from a pre-distorting means and a demodulated signal which is outputted from a demodulating means;
b) at a pre-distortion characteristic predicting means, predicting pre-distortion characteristics based on the pre-distorted signal and the predicted characteristics model of the high power amplifying means; and
c) adapting the predicted pre-distortion characteristics to the pre-distorting means.

4. The method as recited in claim 3, wherein the pre-distortion characteristic predicting means obtains an inverse characteristic function of the high power amplifying means based on the pre-distorted signal and the characteristic model of the high power amplifying means which is obtained by the high power amplifying characteristic predicting means.

5. The method as recited in claim 3, further comprising the step of:
d) repeating the steps of a) to c) for chasing characteristics of a time variable system for a predetermined number of times.
